(19) United States
(12) Patent Application Publication
(10) Pub. No.: US 2009/0321117 A1
(43) Pub. Date: Dec. 31, 2009

(54) A CURABLE EPOXY RESIN COMPOSITION HAVING A MIXED CATALYST SYSTEM AND LAMINATES MADE THEREFROM

(76) Inventors: Ludovic Valette, Shanghai (CN); Tomoyuki Aoyama, Tokyo (JP)

Correspondence Address: The Dow Chemical Company, Intellectual Property Section, P.O. Box 1967, Midland, MI, 48641-1967, US

(21) Appl. No.: 12/097,639

(22) PCT Filed: Dec. 19, 2006
(86) PCT No.: PCT/US06/48484

§ 371 Date: May 18, 2009

Related U.S. Application Data
(60) Provisional application No. 60/753,029, filed on Dec. 22, 2005.

(51) Int. Cl. C08L 67/00; B05D 5/12; B32B 27/04; B32B 27/38; B32B 17/10; B32B 15/092; H05K 1/00

(52) U.S. Cl. 174/258; 523/510; 525/407; 427/58; 442/110; 428/418; 428/417

(57) ABSTRACT

A curable halogen-containing epoxy resin composition comprising: (a) at least one epoxy resin; (b) at least one hardener; wherein the hardener is a compound containing a phenolic hydroxyl functionality or a compound capable of generating a phenolic hydroxyl functionality upon heating; and (c) a catalytic amount of a catalyst system comprising a combination of: (i) at least a first catalyst compound comprising at least one nitrogen-containing catalyst compound; and (ii) at least a second catalyst compound comprising at least one phosphorus-containing catalyst compound; wherein at least one or more of the above components (a)-(c) is halogenated or contains halogen; or if none of the above components are halogenated wherein the resin composition includes (d) a halogenated or halogen-containing flame retardant compound that does not contain nitrogen. The stroke cure gel time of the resin composition is maintained from 90 seconds to 600 seconds when measured at 170° C.; and the cured product formed by curing the curable epoxy resin composition contains well-balanced properties. The composition may be used to obtain a prepreg or a metal-coated foil, or a laminate by laminating the above prepreg and/or the above metal-coated foil. The laminate shows a combination of superior glass transition temperature, decomposition temperature, time to delamination at 288° C., adhesion to copper foil, and excellent flame retardancy.

The present invention relates to thermosetting epoxy resin compositions containing a certain catalyst system, to processes utilizing these compositions and to articles made from these compositions. More specifically, the present invention relates to an epoxy resin composition including a mixed catalyst system comprising (i) a nitrogen-containing catalyst and (ii) a phosphorus-containing catalyst. Articles prepared from the resin compositions of the present invention exhibit enhanced thermal properties and other well-balanced properties. The resin compositions of the present invention may be used for any purpose, but are particularly suited to be utilized in the manufacture of laminates, more specifically, electrical laminates for printed circuit boards. The electrical laminates prepared from the compositions of the present invention have superior thermal stability and excellent balance of properties.

Articles prepared from resin compositions which have improved resistance to elevated temperatures are desirable for many applications. In particular these articles, having improved elevated temperature resistance, are desirable for printed circuit board (PCB) applications due to industry trends which include higher circuit densities, increased board thickness, lead free solders, and higher temperature use environments.

Articles such as laminates, and particularly structural and electrical copper clad laminates, are generally manufactured by pressing, under elevated temperatures and pressures, various layers of partially cured prepregs and optionally copper sheeting. Prepregs are generally manufactured by impregnating a curable thermosettable epoxy resin composition into a porous substrate, such as a glass fiber mat, followed by processing at elevated temperatures to promote a partial cure of the epoxy resin in the mat to a “B-stage.” Complete cure of the epoxy resin impregnated in the glass fiber mat typically occurs during the lamination step when the prepreg layers are pressed under high pressure and elevated temperatures for a time sufficient to allow for complete cure of the resin when preparing a laminate.

While epoxy resin compositions are known to impart enhanced thermal properties for the manufacture of prepregs and laminates, such epoxy resin compositions are typically more difficult to process, more expensive to formulate, and may suffer from inferior performance capabilities for complex printed circuit board circuitry and for higher fabrication and usage temperatures.

In light of the above, there is a need in the art for epoxy resin compositions for preparing articles having improved thermal properties and for processes to produce such articles. There is also a need in the art for inexpensive resin compositions for achieving enhanced thermal properties and for articles, especially prepregs and laminates, having enhanced thermal properties.

In particular, there continues to be a need for higher thermally resistant laminates used as substrates for PCB in order to manage lead-free soldering temperatures and higher in-use thermal exposure requirements. Standard FR-4 laminates normally used in PCBs are made of brominated epoxy resins cured with dicyandiamide. These standard FR-4 laminates have low thermally stability, that is a low degradation temperature (Td) and a short time to delamination at 288° C. (T288).

Improved thermal stability can be achieved when a phenolic or an anhydride hardener is used instead of dicyandiamide in a varnish formulation for making laminates. However, such varnishes have a narrow processing window. Often the resulting laminate from such varnish has a lower glass transition temperature (Tg), and a lower adhesion to copper foil. The laminates are also more brittle.

High molecular weight carboxylic anhydrides are also known to be used as curing agents. The use of high molecular weight carboxlic anhydride as curing agents leads to poor prepreg cosmetics due to the high melt viscosity of the prepreg powder. The prepreg is usually more brittle, resulting in the formation of dust when such prepreg is cut and trimmed. The formation of dust is referred to in the art as a “mushroom effect”.

It is typical in the known art that the improvement of one property of an epoxy resin or a laminate made therefrom is usually achieved at the expense of another property, and not all properties can be improved at the same time. Some known processes use expensive specialty resins and hardeners in an attempt to achieve a resin with well-balanced properties.

The use of non-brominated epoxy resins can, for example, provide laminates with a high thermal stability. However, the use of non-brominated flame retardant epoxy resins is limited because of their higher price when compared to standard FR-4 laminate resins. Also, the use of non-brominated epoxy resins leads to a poor balance of properties of the resulting laminates. For example, a laminate made from a non-brominated epoxy resin may exhibit a lower Tg, a higher brittleness, and a higher sensitivity to moisture.

In spite of improvements made to compositions and processes for making electrical laminates, none of the known prior art references disclose a resin composition useful for making a laminate with a good balance of laminate properties and thermal stability, such as high Tg, good toughness, and good adhesion to copper foil.

It would be desirable to provide a curable epoxy resin composition with excellent properties well-balanced for use as a material for making a laminate such that the laminate has excellent well-balanced laminate properties. It would also be desirable to achieve a laminate having high thermal stability with high Tg, good toughness, and good adhesion to copper foil without the use of expensive specialty resins or hardeners.

One aspect of the present invention is directed to halogen-containing curable epoxy resin composition comprising: (a) at least one epoxy resin; (b) at least one hardener wherein the hardener is a compound containing a phenolic hydroxyl functionality or a compound capable of generating a phenolic hydroxyl functionality upon heating; and (c) a catalytic amount of a catalyst system comprising a combination of: (i) at least a first catalyst comprising at least one nitrogen-containing catalyst compound, and (ii) at least a second catalyst comprising at least one phosphorus-containing catalyst compound that does not contain nitrogen; wherein at least one or more of the above components (a)-(c) is halogenated or contains halogen; or if none of the above components is halogenated wherein the resin composition includes (d) a halogenated or halogen-containing flame retardant compound; characterized in that the stroke cure gel time of the resin composition is maintained from 90 seconds to 600 seconds when measured at 170° C.; and such that a resultant cured product formed by curing the curable epoxy resin composition contains the following well-balanced properties: (1) a glass transition temperature (Tg) of greater than 130° C.; (2) a decomposition temperature (Td) of greater than 320° C.; (3) a time to delamination at 288° (T288) of greater than 1 minute; (4) an adhesion to copper of greater than 10 N/cm; and (5) a UL94 flame retardancy ranking of at least V-1.

Another aspect of the present invention is directed to the use of the above composition to obtain a prepreg or a metal-coated foil; and to a laminate obtained by laminating the above prepreg and/or the above metal-coated foil. The resultant laminate shows a combination of well-balanced properties including superior glass transition temperature, decomposition temperature, time to delamination at 288° C., and adhesion to copper foil.

Generally, the present invention includes a curable halogen-containing epoxy resin composition including the following components: (a) at least one epoxy resin; (b) at least one hardener; wherein the hardener is a compound containing a phenolic hydroxyl functionality or a compound capable of generating a phenolic hydroxyl functionality upon heating; (c) a catalyst system, comprising a combination of two or more catalyst compounds wherein the catalyst system contains: (i) at least a first catalyst comprising at least one nitrogen atom-containing compound and (ii) at least a second catalyst comprising at least one compound that does not contain a nitrogen atom such as a phosphorus-containing catalyst compound; wherein at least one or more of the above components (a)-(c) is halogenated or contains halogen; or if none of the above components is halogenated wherein the resin composition includes (d) a halogenated or halogen-containing flame retardant compound; wherein said curable epoxy resin composition, after curing, provides a cured product with excellent balance of properties. In the above halogen-containing epoxy resin composition at least one or more of components (a), (b), or (c) may be halogen-containing and have flame retardant properties. If none of the components (a)-(c) are halogen-containing, then in order for the final resin composition to be halogen-containing an additional component such as (d) a halogenated flame retardant compound may optionally be added to the resin composition.

The curable epoxy resin composition of the present invention, after curing, provides a cured product, for example a laminate, with excellent balance of properties including, for example, glass transition temperature (Tg), decomposition temperature (Td), time to delamination at 288° C. (T288), adhesion to copper foil (copper peel strength), and flame retardancy (a flame retardancy ranking of at least UL94 V-1, preferably UL94 V-0).

The present invention provides an improved epoxy resin system that can be used for making electrical laminates, including prepregs and laminates for PCB. The curable epoxy resin composition of the present invention can give a cured product having excellent balance of the following properties, for example: Tg, Td, T288, adhesion and flame retardancy while not detrimentally effecting other properties such as toughness, moisture resistance, dielectric constant (Dk) and dielectric loss factor (Df), thermomechanical properties (coefficient of thermal expansion, modulus), and processing window and cost. The composition provides prepregs and laminates with high thermal stability and excellent overall balance of properties, that is, high Tg, high adhesion and good toughness.

Generally, the present invention includes the use of a mixed catalyst system, of preferably two or more co-catalysts, in an epoxy-containing varnish, preferably with a phenolic hardener. The combination of catalysts in the present invention includes a catalyst that does not contain a nitrogen atom, such as triphenyl phosphine or phosphonium acid derivatives, and a nitrogen-containing catalyst, such as imidazole. The relative concentration of the co-catalysts directly influences gel time and other varnish properties. In addition, it has been found that there is an unexpected relationship between the thermal stability of the fully cured laminate and the relative concentration of catalysts. The lower the concentration of imidazole, the higher the thermal stability. For example, the use of a combination of imidazole and triphenyl phosphine allows for controlling varnish reactivity and other varnish, prepreg, and laminate properties (for example Tg). The improvement of thermal stability is observed when phenolic hardeners, for example, are used to cure epoxy resins.

The properties of the cured product that are well-balanced in accordance with the present invention include: a glass transition temperature (Tg) of greater than 130° C., more preferably a Tg of greater than 140° C., preferably a Tg of greater than 150° C., and even more preferably a Tg of greater than 170° C.; a decomposition temperature (Td) of greater than 320° C., preferably a Td of greater than 330° C., more preferably a Td of greater than 340° C., and even more preferably a Td of greater than 350° C.; a time to delamination at 288° C. (T288) of greater than 1 minute, preferably a T288 of greater than 5 minutes, more preferably a T288 of greater than 10 minutes, and even more preferably a T288 of greater than 15 minutes; an adhesion to copper foil (conventional 1 oz copper foil) such as a peel strength of greater than 10 N/cm, preferably a peel strength of greater than 12 N/cm, and more preferably a peel strength of greater than 16 N/cm; and a flame retardancy in terms of a UL94 ranking of at least V-1 and preferably V-0.

The curable halogen-containing epoxy resin composition of the present invention includes at least one epoxy resin component. Epoxy resins are those compounds containing at least one vicinal epoxy group. The epoxy resin may be saturated or unsaturated, aliphatic, cycloaliphatic, aromatic or heterocyclic and may be substituted. The epoxy resin may also be monomeric or polymeric.

Preferably the epoxy resin component is a polyepoxide. Polyepoxide as used herein refers to a compound or mixture of compounds containing more than one epoxy moiety. Polyepoxide as used herein includes partially advanced epoxy resins that is, the reaction of a polyepoxide and a chain extender, wherein the reaction product has, on average, more than one unreacted epoxide unit per molecule. Aliphatic polyepoxides may be prepared from the known reaction of epihalohydrins and polyglycols. Other specific examples of aliphatic epoxides include trimethylpropane epoxide, and diglycidyl-1,2-cyclohexane dicarboxylate. Preferable compounds which can be employed herein include, epoxy resins such as, for example, the glycidyl ethers of polyhydric phenols, that is, compounds having an average of more than one aromatic hydroxyl group per molecule such as, for example, dihydroxy phenols, biphenols, bisphenols, halogenated biphenols, halogenated bisphenols, alkylated biphenols alkylated bisphenols, trisphenols, phenolaldehyde novolac resins, substituted phenolaldehyde novolac resins, phenol-hydrocarbon resins, substituted phenol-hydrocarbon resins and any combination thereof.

Preferably, the epoxy resins used in the resin composition of the present invention is at least one halogenated or halogen-containing epoxy resin compound. Halogen-containing epoxy resins are compounds containing at least one vicinal epoxy group and at least one halogen. The halogen can be, for example, chlorine or bromine, and is preferably bromine. Examples of halogen-containing epoxy resins useful in the present invention include diglycidyl ether of tetrabromobisphenol A and derivatives thereof. Examples of the epoxy resin useful in the present invention include commercially available resins such as D.E.R.™ 500 series, commercially available from The Dow Chemical Company.

The halogen-containing epoxy resin may be used alone, in combination with one or more other halogen-containing epoxy resins, or in combination with one or more other different non-halogen-containing epoxy resins. The ratio of halogenated epoxy resin to non-halogenated epoxy resin is preferably chosen to provide flame retardancy to the cured resin. The weight amount of halogenated epoxy resin which may be present may vary depending upon the particular chemical structure used (due to the halogen content in the halogenated epoxy resin), as is known in the art. It also depends on the fact that other flame retardants might be present in the composition, including the curing agent and optional additives. The preferred halogenated flame retardants are brominated, preferably diglycidyl ether of tetrabromobisphenol A and derivatives thereof.

In one embodiment, the ratio of halogenated epoxy resin to non-halogenated epoxy resin used in the composition of the present invention is such that the total halogen content in the composition is between 2 percent and 40 percent by weight based on solids (excluding fillers), preferably between 5 percent and 30 percent, and more preferably between 10 percent and 25 percent. In another embodiment, the ratio of halogenated epoxy resin to non-halogenated epoxy resin used in the composition of the present invention is between 100:0 and 2:98 by weight, preferably between 100:0 and 10:90, and more preferably between 90:10 and 20:80. In another embodiment, the ratio of halogenated epoxy resin to non-halogenated epoxy resin used in the composition of the present invention is such that the total halogen content in the epoxy resin is between 2 percent and 50 percent by weight based on solids, preferably between 4 percent and 40 percent, and more preferably between 6 percent and 30 percent.

The epoxy resin compounds other than the halogen-containing epoxy resin utilized in the composition of the present invention may be, for example, an epoxy resin or a combination of epoxy resins prepared from an epihalohydrin and a phenol or a phenol type compound, prepared from an epihalohydrin and an amine, prepared from an epihalohydrin and a carboxylic acid, or prepared from the oxidation of unsaturated compounds.

In one embodiment, the epoxy resins utilized in the compositions of the present invention include those resins produced from an epihalohydrin and a phenol or a phenol type compound. The phenol type compound includes compounds having an average of more than one aromatic hydroxyl group per molecule. Examples of phenol type compounds include dihydroxy phenols, biphenols, bisphenols, halogenated biphenols, halogenated bisphenols, hydrogenated bisphenols, alkylated biphenols, alkylated bisphenols, trisphenols, phenol-aldehyde resins, novolac resins (that is the reaction product of phenols and simple aldehydes, preferably formaldehyde), halogenated phenol-aldehyde novolac resins, substituted phenol-aldehyde novolac resins, phenol-hydrocarbon resins, substituted phenol-hydrocarbon resins, phenol-hydroxybenzaldehyde resins, alkylated phenol-hydroxybenzaldehyde resins, hydrocarbon-phenol resins, hydrocarbon- halogenated phenol resins, hydrocarbon-alkylated phenol resins, or combinations thereof.

In another embodiment, the epoxy resins utilized in the compositions of the invention preferably include those resins produced from an epihalohydrin and bisphenols, halogenated bisphenols, hydrogenated bisphenols, novolac resins, and polyalkylene glycols, or combinations thereof. Examples of bisphenol A based epoxy resins useful in the present invention include commercially available resins such as D.E.R.™ 300 series and D.E.R™ 600 series, commercially available from The Dow Chemical Company. Examples of epoxy Novolac resins useful in the present invention include commercially available resins such as D.E.N.™ 400 series, commercially available from The Dow Chemical Company.

In another embodiment, the epoxy resin compounds utilized in the compositions of the invention preferably include those resins produced from an epihalohydrin and resorcinol, catechol, hydroquinone, biphenol, bisphenol A, bisphenol AP (1,1-bis(4-hydroxyphenyl)-1-phenyl ethane), bisphenol F, bisphenol K, tetrabromobisphenol A, phenol-formaldehyde novolac resins, alkyl substituted phenol-formaldehyde resins, phenol- hydroxybenzaldehyde resins, cresol-hydroxybenzaldehyde resins, dicyclopentadiene-phenol resins, dicyclopentadiene-substituted phenol resins, tetramethylbiphenol, tetramethyl-tetrabromobiphenol, tetrarnethyltribromobiphenol, tetrachlorobisphenol A, or combinations thereof. Preferably the epoxy resin contains diglycidyl ether of tetrabromobisphenol A.

The preparation of such compounds is well known in the art. See Kirk-Othmer, Encyclopedia of Chemical Technology, 3rd Ed., Vol. 9, pp 267-289. Examples of epoxy resins and their precursors suitable for use in the compositions of the invention are also described, for example, in U.S. Pat. Nos. 5,137,990 and 6,451,898.

In another embodiment, the epoxy resins utilized in the compositions of the present invention include those resins produced from an epihalohydrin and an amine. Suitable amines include diaminodiphenylmethane, aminophenol, xylene diamine, anilines, or combinations thereof.

In another embodiment, the epoxy resins utilized in the compositions of the present invention include those resins produced from an epihalohydrin and a carboxylic acid. Suitable carboxylic acids include phthalic acid, isophthalic acid, terephthalic acid, tetrahydro- and/or hexahydrophthalic acid, endomethylenetetrahydrophthalic acid, isophthalic acid, methylhexahydrophthalic acid, or combinations thereof.

In another embodiment the epoxy resin refers to an advanced epoxy resin which is the reaction product of one or more epoxy resins components, as described above, with one or more phenol type compounds and/or one or more compounds having an average of more than one aliphatic hydroxyl group per molecule as described above. Alternatively, the epoxy resin may be reacted with a carboxyl substituted hydrocarbon, which is described herein as a compound having a hydrocarbon backbone, preferably a C₁-C₄₀ hydrocarbon backbone, and one or more carboxyl moieties, preferably more than one, and most preferably two. The C₁-C₄₀ hydrocarbon backbone may be a straight- or branched-chain alkane or alkene, optionally containing oxygen Fatty acids and fatty acid dimers are among the useful carboxylic acid substituted hydrocarbons. Included in the fatty acids are caproic acid, caprylic acid, capric acid, octanoic acid, decanoic acid, lauric acid, myristic acid, palm itic acid, stearic acid, pal mitoleic acid, oleic acid, linoleic acid, linolenic acid, erucic acid, pentadecanoic acid, margaric acid, arachidic acid, and dimers thereof.

The epoxy resin, Component (a), of the present invention may be selected from, for example, oligomeric and polymeric diglycidyl ether of bisphenol A, oligomeric and polymeric diglycidyl ether of tetrabromobisphenol A, oligomeric and polymeric diglycidyl ether of bisphenol A and tetrabromobisphenol A, epoxydized phenol Novolac, epoxydized bisphenol A Novolac, oxazolidone-modified epoxy resins and mixtures thereof.

In another embodiment, the epoxy resin is the reaction product of a polyepoxide and a compound containing more than one isocyanate moiety or a polyisocyanate. Preferably, the epoxy resin produced in such a reaction is an epoxy-terminated polyoxazolidone.

In one embodiment, the curing agent (also referred to as a hardener or a crosslinker), Component (b), utilized in the composition of the present invention includes at least one hardener compound with at least one phenolic hydroxyl functionality, a hardener compound capable of generating at least one phenolic hydroxyl functionality, or mixtures thereof. Preferably, the curing agent is a compound or a mixture of compounds with a phenolic hydroxyl functionality.

Examples of compounds with a phenolic hydroxyl functionality (the phenolic curing agent) include compounds having an average of one or more phenolic groups per molecule. Suitable phenol curing agents include dihydroxy phenols, biphenols, bisphenols, halogenated biphenols, halogenated bisphenols, alkylated biphenols, alkylated bisphenols, trisphenols, phenol-aldehyde resins, phenol- aldehyde novolac resins, halogenated phenol-aldehyde novolac resins, substituted phenol-aldehyde novolac resins, phenol-hydrocarbon resins, substituted phenol-hydrocarbon resins, phenol-hydroxybenzaldehyde resins, alkylated phenol-hydroxybenzaldehyde resins, hydrocarbon-phenol resins, hydrocarbon-halogenated phenol resins, hydrocarbon-alkylated phenol resins, or combinations thereof. Preferably, the phenolic curing agent includes substituted or unsubstituted phenols, biphenols, bisphenols, novolacs or combinations thereof.

The curing agent of the present invention may be selected from, for example, phenol novolac, bisphenol A novolac, bisphenol A, tetrabromobisphenol A and mixtures thereof.

The curing agent may also include any of the multi-functional phenolic cross-linkers described in U.S. Pat. No. 6,645,631 Column 4, lines 57-67 to Column 6 lines 1-57.

In one embodiment, the curing agent contains an halogenated flame retardant. Preferably the halogenated flame retardant is a brominated flame retardant. More preferably, the brominated flame retardant is a brominated phenolic compound, such as tetrabromobisphenol A or derivatives.

Examples of curing agents capable of generating phenolic hydroxyl functionalities are monomeric and oligomeric benzoxazines and polybenzoxazines. By “generating” herein it is meant that upon heating the curing agent compound, the curing agent compound transforms into another compound having phenolic hydroxyl functionalities, which acts as a curing agent. Examples of component (b) curing agents may also include compounds which form a phenolic cross-linking agent upon heating for example species obtained from heating bezoxazines as described in U.S. Pat. No. 6,645,631. Examples of such components also include benzoxazine of phenolphthalein, benzoxazine of bisphenol-A, benzoxazine of bisphenol-F, benzoxazine of phenol novolac. Mixtures of such components described above may also be used.

In another embodiment, one or several co-curing agents that do not contain phenolic hydroxyl functionality or capable of generating phenolic hydroxyl functionality are present in the composition. Co-curing agents useful in this invention are those compounds known to the skilled in the art to react with polyepoxides or advanced epoxy resins to form hardener final products. Such co-curing agents include, but are not limited to, amino-containing compounds, such as amines and dicyandiamide, and carboxylic acids and carboxylic anhydrides, such as styrene-maleic anhydride polymer. Preferably the molar ratio of curing agent to co-curing agent (the molar ratio is calculated based on the active groups capable of reacting with epoxides) is between 100:0 and 50:50, preferably between 100:0 and 60:40, more preferably between 100:0 and 70:30, and even more preferably between 100:0 and 80:20. Preferably the weight ratio of curing agent to co-curing agent is between 100:0 and 50:50, more preferably between 100:0 and 60:40, even more preferably between 100:0 and 70:30, and most preferably between 100:0 and 80:20.

The ratio of curing agent to epoxy resin is preferably suitable to provide a fully cured resin. The amount of curing agent which may be present may vary depending upon the particular curing agent used (due to the cure chemistry and curing agent equivalent weight) as is known in the art. In one embodiment, the molar ratio between the epoxy groups of the epoxy resin Component (a) and the reactive hydrogen groups of the hardener Component (b) is between 1:2 and 2:1, preferably between 1.5:1 and 1:1.5, and more preferably between 1.2:1 and 1:1.2. If a co-curing agent is used in combination with the phenolic curing agent, then the molar ratios described above should be based on the combination of curing agents.

The curing catalyst, (also referred to as a curing accelerator), Component (c), used in the epoxy resin composition of the present invention is a mixture of two or more catalyst compounds (co-catalysts), which promotes the reaction between epoxy groups in the epoxy resin and active groups in the hardener.

The mixed catalyst system of the present invention acts with the curing agent to form an infusible reaction product between the curing agent and the epoxy resin in a final article of manufacture such as a structural composite or laminate. By an infusible reaction product, it is meant that the epoxy resin has essentially completely cured, which for example may be at a time when there is little or no change between two consecutive Tg measurements (ΔTg).

In one embodiment, the catalyst of the present invention includes a combination of: (i) at least one nitrogen-containing catalyst compound and (ii) at least one catalyst compound that does not contain a nitrogen atom, more particularly, an organic phosphorus-containing catalyst compound. The catalyst of the present invention includes a combination of (i) nitrogen-containing compounds, like amines, imidazoles, amides, and combinations thereof; and (ii) phospohorus-containing compounds, like phosphines, phosphonium compounds, and combinations thereof.

The nitrogen-containing catalyst, Component (c) (i), of the present invention may be selected, for example, from the group consisting of amines, amides, substituted imidazoles, and non-substituted imidazoles, and combinations thereof. Preferably, the first catalyst is a nitrogen-containing compound which includes a heterocyclic nitrogen compound, an amine, and an ammonium compound. Examples of suitable catalyst compounds also include those compounds listed in European Patent Specification EP 0 954 553B1.

Examples of amines include 2,4,6-tris(dimethylaminomethyl)phenol, benzyldimethylamine, tetramethylbutylguanidine, N-methylpiperazine or 2-dimethylamino-1-pyrroline.

Examples of ammonium salts include tri-ethylammonium tetraphenylborate.

Examples of diazabicyclo compounds include 1,5-diazabicyclo(5,4,0)-7-undecene, 1,5-diazabicyclo (4,3,0)-5-nonene or 1,4-diazabicyclo(2,2,2)-octane; and tetraphenyl borates, phenol salts, phenol novolak salts or 2-ethylhexanoic acid salts of this diazabicyclo compounds.

Preferably the nitrogen-containing catalyst compound is an imidazole, derivative of an imidazole, or mixtures thereof. Examples of suitable imidazoles include 2-methylimidazole, 2-phenyl imidazole, 2-ethyl-4-methyl imidazole, 2-undecylimidazole, 1-cyanoethyl-2-methylimidazole, 2-undecylimidazole, 1-cyanoethyl-2-methylimidazole, 2,4-dicyano-6-[2-methylimidazolyl-(1)]-ethyl-S-triazine or 2,4-dicyano-6-[2-methylimidazolyl-(1)]-ethyl-S-triazine; and combinations thereof. Derivatives of imidazole include for example imidazolium salts such as 1-cyanoethyl-2-undecylimidazolium trimellitate, 2-methylimidazolium isocyanurate, 2-ethyl-4-methylimidazolium tetraphenylborate or 2-ethyl-1,4-dimethylimidazolium tetraphenylborate and combinations thereof.

Catalysts that do not contain a nitrogen atom, Component (c) (ii), useful in the present invention are phosphorus-containing compounds including, for example, triphenyl phosphine and phosphonium acid derivatives, and mixtures thereof. Preferably, the second catalyst that does not contain a nitrogen atom includes phosphine compounds, phosphonium compounds, arsonium compounds, or sulfonium compounds, or combinations thereof More preferably, the second catalyst is a phosphorus-containing compound such as a phosphine compound, a phosphonium compound or a combination thereof.

Examples of the phosphorus-containing curing accelerator include, but not limited to, phosphine compounds such as tributyl phosphine, triphenyl phosphine, tris(dimethoxyphenyl)phosphine or tris(hydroxypropyl)phosphine, tris(cyanoethyl)phosphine; phosphonium compounds, such as tetraphenylphosphonium tetraphenylborate, methyltributylphosphonium tetraphenylborate, methyltributylphosphonium tetraphenylborate, or methyltricyanoethylphosphonium tetraphenylborate.

Listed as specific examples of organic phosphorus compounds are tri-n-propylphosphine, tri-n-butylphosphine, triphenylphosphine, tetramethylphosphonium bromide, tetramethylphosphonium iodide, tetramethylphosphonium hydroxide, trimethylcyclohexylphosphonium chloride, trimethylcyclohexylphosphonium bromide, trimethylbenzylphosphonium chloride, trimethylbenzylphosphonium bromide, tetraphenylphosphonium bromide, triphenylmethylphosphonium bromide, triphenylmethylphosphonium iodide, tetraphenylethylphosphonium chloride, triphenylethylphosphonium bromide, triphenylethylphosphonium iodide, triphenylbenzylphosphonium chloride, triphenylbenzylphosphonium bromide, and combinations thereof.

The amount of catalyst utilized in the epoxy resin composition of the present invention is an amount effective to catalyze the reaction of the epoxy resin with the curing agent. As known in the art, the amount of catalyst to be utilized depends upon the components utilized in the composition, the processing requirements, and the performance targets of the articles to be manufactured. In one embodiment, the amount of curing accelerators used is preferably from 0.001 to 10 percent by weight to the epoxy resin (a) (based on solids), more preferably from 0.01 to 5 percent by weight, even more preferably from 0.02. to 2 percent by weight, and even most preferably from 0.04 percent to 1 percent by weight. The amount of curing accelerators can be adjusted to achieve suitable reactivity characterized by the gel time at 170° C. In general, the stroke cure gel time of the resin at 170° C. is maintained between 90 second (s) and 600 s, preferably between 120 s and 480 s, and more preferably between 180 s and 420 s.

In one embodiment, the ratio of nitrogen-containing catalyst to non nitrogen-containing compound is preferably from 95:5 to 5:95 by weight (on solids), preferably between 90:10 and 10:90, and more preferably between 80:20 and 20:80.

The entire catalyst system, Component (c), or part of the catalyst system can be conveniently incorporated into the hardener Component (b).

Generally, the flame retardant compound, Component (d), used in the composition of the present invention is a halogenated compound. Preferred flame retardants are brominated flame retardants. Examples of brominated flame retardants include halogenated epoxy resins (especially brominated epoxy resins), tetrabromobisphenol A (TBBA) and its derivatives, D.E.R.™ 542, D.E.R.™ 560 which are available from The Dow Chemical Company, a brominated phenol novolac and its glycidyl ether, TBBA epoxy oligomer, TBBA carbonate oligomer, brominated polystyrene, polybromo phenylene oxide, hexabromo benzene, and tetrabromobisphenol-S and mixtures thereof. Optionally, the flame retardant may be incorporated, partly or as a whole, in the epoxy resin (a), the phenolic hardener (b), or a combination thereof. Examples of suitable additional flame retardant additives are given in a paper presented at “Flame retardants—101 Basic Dynamics—Past efforts create future opportunities”, Fire Retardants Chemicals Association, Baltimore Marriot Inner Harbour Hotel, Baltimore Md., Mar. 24-27, 1996.

Optionally, the curable epoxy resin composition of the present invention may further contain other components typically used in an epoxy resin composition particularly for making prepegs and laminates; and which do not detrimentally affect the properties or performance of the composition of the present invention, or the final cured product therefrom. For example, other optional components useful in the epoxy resin composition may include toughening agents; curing inhibitors; fillers; wetting agents; colorants; flame retardants; solvents; thermoplastics; processing aids; fluorescent compound; such as tetraphenolethane (TPE) or derivatives thereof; UV blocking compounds; and other additives. The epoxy resin compositions of the present invention may also include other optional constituents such as inorganic fillers and additional flame retardants, for example antimony oxide, octabromodiphenyl oxide, decabromodiphenyl oxide, phosphoric acid and other such constituents as is known in the art including, but not limited to, dyes, pigments, surfactants, flow control agents, plasticizers.

In one embodiment, the epoxy resin composition may optionally contain a toughening agent that creates phase-separated micro-domains. Preferably, the toughening agent creates phase-separated domains or particles, which average size is lower than 5 micron, preferably lower than 2 micron, more preferably lower than 500 nm, and even more preferably lower than 100 nm. Preferably, the toughening agent is a block copolymer toughening agent, more preferably the toughening agent is a triblock toughening agent, or the toughening agent consists of pre-formed particles, preferably core-shell particles. In particular, the triblock copolymer could have polystyrene, polybutadiene, and poly(methyl methacrylate) segments or poly(methyl methacrylate) and poly(butyl acrylate) segments. Preferably, the toughening agent does not substantially reduce Tg of the cured system, that is reduction of Tg<15° C., preferably <10° C., more preferably <5° C. When present, the concentration of toughening agent is between 0.1 and 30 phr, preferably between 0.5 and 20 phr, more preferably between 1 and 10 phr, and even more preferably between 2 and 8 phr.

In the case of high Tg laminates, the use of a toughening agent may be needed to improve toughness and adhesion to copper. Block copolymers such as styrene-butadiene-methyl methacrylate (SBM) polymer are very suitable because they improve toughness without negative influence on other laminates properties, such as Tg, Td, and water uptake. Especially advantageous is a the combination of a catalyst adjuvant in an epoxy-containing varnish and a block copolymer toughening agent, such as SBM polymer, in an epoxy-containing varnish, preferably with a phenolic hardener, leads to laminates with excellent balance of properties, that is high Td, high Tg, and good toughness.

In another embodiment, the epoxy resin composition may optionally contain a fluorescent and a UV blocking compound, such as tetraphenolethane. Preferably, the fluorescent compound is tetraphenol ethane (TPE) or derivatives. Preferably, the UV blocking compound is TPE or derivatives.

In another embodiment, the composition of the present invention may contain a cure inhibitor, such as boric acid. In one embodiment, the amount of boric acid is preferably from 0.01 to 3 percent by weight to the epoxy resin (a) (based on solids), more preferably from 0.1 to 2 percent by weight, and more preferably from 0.2 to 1.5 percent by weight. In this embodiment, it is particularly useful to maintain the presence of a portion of imidazole catalyst since boric acid forms complexes with imidazoles which act as latent catalyst for the composition.

The epoxy resin composition of the present invention may also optionally contain a solvent with the other components of the composition; or any of the other components such as the epoxy resin, curing agent, and/or catalyst compound may optionally be used in combination with or separately be dissolved in a solvent. Preferably, the concentration of solids in the solvent is at least 50 percent and no more than 90 percent solids, preferably between 55 percent and 80 percent, and more preferably between 60 percent and 70 percent solids. Non-limiting examples of suitable solvents include ketones, alcohols, water, glycol ethers, aromatic hydrocarbons and mixtures thereof. Preferred solvents include acetone, methyl ethyl ketone, methyl isobutyl ketone, cyclohexanone, methylpyrrolidinone, propylene glycol monomethyl ether, propylene glycol monomethyl ether acetate, ethylene glycol monomethyl ether, methyl amyl ketone, methanol, isopropanol, toluene, xylene, dimethylformamide (DMF). A single solvent may be used, but also separate solvents may be used for one or more components. Preferred solvents for the epoxy resins and curing agents are ketones, including acetone, methylethyl ketone, and ether alcohols such as methyl, ethyl, propyl or butyl ethers of ethylene glycol, diethylene glycol, propylene glycol or dipropylene glycol, ethylene glycol monomethyl ether, or 1-methoxy-2-propanol, and the respective acetates. Preferred solvents for the catalyst of the present invention include alcohols, ketones, water, dimethylformamide (DM), glycol ethers such as propylene glycol monomethyl ether or ethylene glycol monomethyl ether, and combinations thereof.

As an illustration of one embodiment of the present invention, typical components of the composition of the present invention include:

(a) an epoxy resin such as oligomeric and polymeric diglycidyl ether of bisphenol A, oligomeric and polymeric diglycidyl ether of tetrabromobisphenol A, oligomeric and polymeric diglycidyl ether of bisphenol A and tetrabromobisphenol A, epoxydized phenol novolac, epoxydized bisphenol A novolac, oxazolidone-containing epoxy resin, or mixture thereof;

(b) a phenolic hardener such as phenol novolac, bisphenol A novolac, bisphenol A, tetrabromobisphenol A, monomeric and oligomeric and polymeric benzoxazine, or a mixture thereof;

(c) a blend of (i) nitrogen-containing catalyst such as imidazole; and (ii) phosphorus-containing catalyst such as tripehnylphosphine; and

(d) a flame retardant additive such as TBBA and derivatives thereof.

The components of the compositions of the present invention may be mixed together in any order. Preferably, the composition of the present invention can be produced by preparing a first composition comprising the epoxy resin, and a second composition comprising the phenolic hardener. Either the first or the second composition may also comprise a curing catalyst, and/or a flame retardant compound. All other components may be present in the same composition, or some may be present in the first, and some in the second. The first composition is then mixed with the second composition to produce a curable halogen-containing flame retardant epoxy resin composition.

The curable halogen-containing epoxy resin composition of the present invention can be used to make composite materials by techniques well known in the industry such as by pultrusion, molding, encapsulation or coating. The resin compositions of the present invention, due to their thermal properties, are especially useful in the preparation of articles for high temperature continuous use applications. Examples include electrical laminates and electrical encapsulation. Other examples include molding powders, coatings, structural composite parts and gaskets.

The epoxy resin compositions described herein may be found in various forms. In particular, the various compositions described may be found in powder form, hot melt, or alternatively in solution or dispersion. In those embodiments where the various compositions are in solution or dispersion, the various components of the composition may be dissolved or dispersed in the same solvent or may be separately dissolved in a solvent or solvents suitable for that component, then the various solutions are combined and mixed. In those embodiments wherein the compositions are partially cured or advanced, the compositions of the present invention may be found in a powder form, solution form, or coated on a particular substrate.

In one embodiment, the present invention provides for a process for preparing a resin coated article. The process steps include contacting an article or a substrate with an epoxy resin composition of the present invention. Compositions of the present invention may be contacted with an article by any method known to those skilled in the art. Examples of such contacting methods include powder coating, spray coating, die coating, roll coating, resin infusion process, and contacting the article with a bath containing the composition. In a preferred embodiment the article is contacted with the composition in a varnish bath. In another embodiment, the present invention provides for articles, especially prepregs and laminates, prepared by the process of the present invention.

The present invention also provides a prepreg obtained by impregnating reinforcement with the composition of the present invention.

The present invention also provides a metal-coated foil obtained by coating a metal foil with the composition of the present invention.

The present invention also provides a laminate with enhanced properties obtained by laminating the above prepreg and/or the above metal-coated foil.

The curable epoxy resin composition of the present invention is amenable to impregnation of reinforcements, for example, glass cloth, and cures into products having both heat resistance and flame retardancy, so that the composition is suitable for the manufacture of laminates which have a well-balance of properties, are well-reliable with respect to mechanical strength and electrical insulation at high temperatures. The epoxy resin compositions of the present invention utilizing the epoxy resin curing catalyst of the present invention may be impregnated upon a reinforcing material to make laminates, such as electrical laminates. The reinforcing materials which may be coated with the compositions of the present invention include any material which would be used by one skilled in the art in the formation of composites, prepregs, and laminates. Examples of appropriate substrates include fiber-containing materials such as woven cloth, mesh, mat, fibers, and unwoven aramid reinforcements such as those sold under the trademark THERMOUNT, available from DuPont, Wilmington, Del. Preferably, such materials are made from glass, fiberglass, quartz, paper, which may be cellulosic or synthetic, a thermoplastic resin substrate such as aramid reinforcements, polyethylene, poly(p-phenyleneterephthalamide), polyester, polytetrafluoroethylene and poly(p-phenylenebenzobisthiazole), syndiotatic polystyrene, carbon, graphite, ceramic or metal. Preferred materials include glass or fiberglass, in woven cloth or mat form.

In one embodiment, the reinforcing material is contacted with a varnish bath comprising the epoxy resin composition of the present invention dissolved and intimately admixed in a solvent or a mixture of solvents. The coating occurs under conditions such that the reinforcing material is coated with the epoxy resin composition. Thereafter the coated reinforcing materials are passed through a heated zone at a temperature sufficient to cause the solvents to evaporate, but below the temperature at which the resin composition undergoes significant cure during the residence time in the heated zone.

The reinforcing material preferably has a residence time in the bath of from 1 second to 300 seconds, more preferably from 1 second to 120 seconds, and most preferably from 1 second to 30 seconds. The temperature of such bath is preferably from 0° C. to 100° C., more preferably from 10° C. to 40° C. and most preferably from 15° C. to 30° C. The residence time of the coated reinforcing material in the heated zone is from 0.1 minute to 15 minutes, more preferably from 0.5 minute to 10 minutes, and most preferably from 1 minute to 5 minutes.

The temperature of such zone is sufficient to cause any solvents remaining to volatilize away yet not so high as to result in a complete curing of the components during the residence time. Preferable temperatures of such zone are from 80° C. to 250° C., more preferably from 100° C. to 225° C., and most preferably from 150° C. to 210° C. Preferably there is a means in the heated zone to remove the solvent, either by passing an inert gas through the oven, or drawing a slight vacuum on the oven. In many embodiments the coated materials are exposed to zones of increasing temperature. The first zones are designed to cause the solvent to volatilize so it can be removed. The later zones are designed to result in partial cure of the epoxy resin component (B-staging).

One or more sheets of prepreg are preferably processed into laminates optionally with one or more sheets of electrically- conductive material such as copper. In such further processing, one or more segments or parts of the coated reinforcing material are brought in contact with one another and/or the conductive material. Thereafter, the contacted parts are exposed to elevated pressures and temperatures sufficient to cause the epoxy resin to cure wherein the resin on adjacent parts react to form a continuous epoxy resin matrix between and the reinforcing material. Before being cured the parts may be cut and stacked or folded and stacked into a part of desired shape and thickness. The pressures used can be anywhere from 1 psi to 1000 psi with from 10 psi to 800 psi being preferred. The temperature used to cure the resin in the parts or laminates, depends upon the particular residence time, pressure used, and resin used. Preferred temperatures which may be used are between 100° C. and 250° C., more preferably between 120° C. and 220° C., and most preferably between 170° C. and 200° C. The residence times are preferably from 10 minutes to 120 minutes, and more preferably from 20 minutes to 90 minutes.

In one embodiment, the process is a continuous process where the reinforcing material is taken from the oven and appropriately arranged into the desired shape and thickness and pressed at very high temperatures for short times. In particular such high temperatures are from 180° C. to 250° C., more preferably 190° C. to 210° C., at times of 1 minute to 10 minutes and from 2 minutes to 5 minutes. Such high speed pressing allows for the more efficient utilization of processing equipment. In such embodiments the preferred reinforcing material is a glass web or woven cloth.

In some embodiments it is desirable to subject the laminate or final product to a post cure outside of the press. This step is designed to complete the curing reaction. The post cure is usually performed at from 130° C. to 220° C. for a time period of from 20 minutes to 200 minutes. This post cure step may be performed in a vacuum to remove any components which may volatilize.

The laminate prepared utilizing the composition in accordance with the present invention shows excellent balance of properties, that is a well-balanced combination of superior glass transition temperature (Tg), decomposition temperature (Td), time to delamination at 288° C. (T288), adhesion to copper foil (copper peel strength), and flame retardancy (flame retardancy ranking at least UL94 V-1).

The laminates prepared from the curable epoxy resin composition of the present invention exhibit enhanced thermal properties when compared to laminates utilizing prior art compositions, for example those containing accelerators, such as for example imidazoles without a catalyst adjuvant. In another embodiment, laminates prepared utilizing the catalyst and catalyst adjuvant of the present invention exhibit a well-balanced properties, such as delamination time, delamination temperature, and glass transition temperature (Tg).

The Tg is maintained in ° C., measured by differential scanning calorimetry at a heating rate of 20° C./minute, of at least 90 percent, preferably of at least 95 percent, and even more preferably of at least 98 percent of that for comparable systems prepared utilizing imidazole accelerators. As utilized herein, Tg refers to the glass transition temperature of the thermosettable resin composition in its current cure state. As the prepreg is exposed to heat, the resin undergoes further cure and its Tg increases, requiring a corresponding increase in the curing temperature to which the prepreg is exposed. The ultimate, or maximum, Tg of the resin is the point at which essentially complete chemical reaction has been achieved. “Essentially complete” reaction of the resin has been achieved when no further reaction exotherm is observed by differential scanning calorimetry (DSC) upon heating of the resin.

The time to delamination of laminates prepared utilizing the composition of the present invention as measured with a thermomechanical analyzer at a heating rate of 10° C./min to 288° C. (T288) increases by at least 5 percent, preferably 10 percent, more preferably at least 20 percent, even more preferably at least 50 percent, and most preferably at least 100 percent relative to the delamination time when compared to laminates manufactured utilizing imidazole accelerators above without a catalyst adjuvant.

In addition, the laminates prepared from the compositions of the present invention also show measurable improvement in the thermal properties of the decomposition temperature (Td) at which about 5 percent of the sample weight is lost upon heating. In another embodiment the decomposition temperature Td of laminates of the present invention is increased by at least 2° C., preferably at least 4° C., even more preferably at least 8° C. when compared to laminates manufactured utilizing imidazole accelerators.

In addition to enhanced thermal properties, the non-thermal properties of the laminates prepared from the compositions of the present invention, such as water absorption, a copper peel strength, dielectric constant, and dissipation factor are comparable with those of prior art formulations utilizing known accelerators.

Preferably the epoxy resin compositions of the present invention, after curing, give a cured laminate product with the following excellent balance of properties: superior glass transition temperature (Tg>130° C., preferably Tg>150° C., more preferably Tg>170° C.), decomposition temperature (Td>320° C., preferably Td>330° C., more preferably Td>340° C., even more preferably Td>350° C.), time to delamination at 288° C. (T288>1 min, preferably >5 min, more preferably >10 min, even more preferably >15 min), adhesion to copper foil (copper peel strength >10 N/cm, preferably >12 N/cm, more preferably >16 N/cm), flame retardancy (flame retardancy ranking at least UL94 V-1, preferably UL94 V-0).

Preferably the composition of the present invention also improves the varnish processing window. The viscosity build-up during advancement to prepare prepreg is smoother than for similar systems that do not contain such a composition.

### EXAMPLES

The present invention will be further illustrated with reference to the following Examples. The following Examples are set forth to illustrate various embodiments of the present invention; and are not intended to limit the scope of the present invention. Unless otherwise stated all parts and percentages in the Examples are by weight.

Various terms, abbreviations and designations for the raw materials used in the following Examples are explained as follows:
EEW stands for epoxy equivalent weight (on solids).
HEW stands for phenolic hydroxyl equivalent weight (on solids).
Percent Br stands for bromine content (by weight, on solids).

Epoxy Resin Solution A is a brominated epoxy resin solution, EEW=239, percent Br=19.5 percent, 77 percent solids in a mixture of DOWANOL™ PMA, DOWANOL™ PM and methanol. (DOWANOL is a trademark of The Dow Chemical Company.)

Epoxy Resin Solution B is a solution of a blend of epoxy resins containing an oxazolidone-modified epoxy resin and brominated epoxy resins, EEW=294, percent Br=21.6 percent, 75 percent solids in a mixture of acetone, DOWANOL PMA, DOWANOL PM and methanol.

Epoxy Resin Solution C is a solution of a blend of epoxy resins containing an oxazolidone-modified epoxy resin and brominated epoxy resins, EEW=285, percent Br=18.8 percent, 76 percent solids in a mixture of acetone, DOWANOL PMA and methanol.

Epoxy Resin Solution D is a brominated epoxy resin solution, EEW=203, percent Br=9.3 percent, 82 percent solids in a mixture of MEK, DOWANOL PMA and DOWANOL PM.

Epoxy Resin Solution E is a brominated epoxy resin solution, containing 6 percent (by weight, on solids) of a triblock copolymer toughening agent polystyrene-polybutadiene-polymethyl methacrylate, EEW=220, percent Br=8.7 percent, 74 percent solids in a mixture of MEK, DOWANOL PMA and methanol.

EBPAN stands for Epoxydized Bisphenol A Novolac. The EBPAN used in the Examples has an EEW of 206. Hardener Resin Solution F is a brominated phenolic resin solution, HEW=138, percent Br=22.4 percent, 53 percent solids in a mixture of MEK and DOWANOL PM.

Hardener Resin Solution G is a brominated phenolic resin solution containing 0.5 percent by weight (on solids) of TPP, HEW=140, percent Br=22.5 percent, 60 percent solids in a mixture of MEK and DOWANOL PM.

Hardener Resin Solution H is a brominated phenolic resin solution, HEW=139, percent Br=22.4 percent, 53 percent solids in a mixture of MEK and DOWANOL™ PMA.

Hardener Resin Solution I is a phenolic hardener solution, 50 percent solids in DOWANOL PMA, EEW=105.

Hardener Resin Solution J is an anhydride hardener solution, 50 percent solids in a mixture of MEK and DOWANOL PMA, EEW=398.

Epoxy Resin Solution K is a solution of a brominated epoxy resins containing 7.6 percent (by weight, on solids) of a triblock copolymer toughening agent polystyrene-polybutadiene-polymethyl methacrylate, EEW=221, percent Br=9 percent, 76 percent solids in a mixture of methyl ethyl ketone and DOWANOL PMA.

Epoxy Resin Solution L is a solution of a brominated epoxy resins containing 6.7 percent (by weight, on solids) of a triblock copolymer toughening agent polystyrene-polybutadiene-polymethyl methacrylate, EEW=259, percent Br=20 percent, 74 percent solids in a mixture of methyl ethyl ketone and DOWANOL PMA.

Epoxy Resin Solution M is a solution of a brominated epoxy resins EEW=267, percent Br=27 percent, 76 percent solids in a mixture of methyl ethyl ketone and DOWANOL™ PMA.

PN stands for phenol novolac. The PN used in the Examples has an HEW of 104, and is commercially available from Dynea.

BPAN stands for bisphenol A novolac. The BPAN used in the Examples has a HEW of 120, and is commercially available from Borden Chemical.

TPE stands for tetraphenolethane. The TPE used in the Examples has a HEW of 140, and is commercially available from Borden Chemical.

TBBA stands for tetrabromobisphenol A. The TBBA used in the Examples has percent Br of 59 percent, HEW of 272, and is commercially available from Albemarle.

BPA stands for bisphenol A. The BPA used in the Examples has a HEW of 114, and is commercially available from The Dow Chemical Company.

Dicy stands for dicyandiamide.

DMF stands for N,N-dimethylformamide.

TPP stands for triphenyl phosphine.

2-MI stands for 2-methyl imidazole.

2-PhI stands for 2-phenyl imidazole.

2E-4MI stands for 2-ethyl-4-methyl imidazole.

SBM¹ E-40 is a styrene—butadiene—methyl methacrylate triblock polymer, commercially available from Arkema. (¹SBM is a trademark of Arkema.)

BYK‡-W903 is a wetting and dispersing additive, commercially available from BYK Chemie. (‡BYK is a trademark of BYK Chemie.)

DOWANOL™ PM is a propylene glycol methyl ether, commercially available from The Dow Chemical Company.

DOWANOL PMA is a propylene glycol methyl ether acetate, commercially available from The Dow Chemical Company.

MEK stands for methyl ethyl ketone.

The glass reinforcement used in the Examples is a woven 7628-tyoe E-glass, 731 finish, available from Porcher Industrie.

The copper foil used in the Examples is a standard 35 micron (1 oz) from Gould Electronics of TW grade available from Circuit Foil.

The standard test methods and procedures used in the Examples to measure certain properties are as follows:

| IPC Test | |
|---|---|
| Method | Property Measured |
| IPC-TM-650- | Flammability of laminate [UL94] |
| 2.3.10B | |
| IPC-TM-650- | Resin content of prepreg, by treated weight [resin |
| 2.3.16.1C | content] |
| IPC-TM-650- | Gel time, prepreg materials [prepreg gel time] |
| 2.3.18A | Note: Similar method was used to determine varnish |
| | stroke cure gel time |
| IPC-TM-650- | Thermal stability [Td] |
| 2.3.40 | Note: Td was determined with a heating ramp of 10° |
| | C./min; Experimental error is +/−1° C. |
| IPC-TM-650- | Peel strength of metallic clad laminates [copper |
| 2.4.8C | peel strength (CPS)] |
| IPC-TM-650- | Glass transition temperature and z-axis Thermal |
| 2.4.24C | expansion by Thermal Mechanical Analysis (TMA) |
| | [Coefficient of Thermal Expansion (CTE)] |
| IPC-TM-650- | Time to delamination (TMA Method) [T260, T288, |
| 2.4.24.1 | T300] |
| IPC-TM-650- | Glass transition temperature and cure factor by DSC |
| 2.4.25C | [Tg] |
| | Note: Tg was determined on films with a heating ramp |
| | of 10° C./min and on laminates with a heating ramp |
| | of 20° C./min; Experimental error is +/−1° C. |
| IPC-TM-650- | Permittivity and loss tangent, parallel plate, 1 MHz |
| 2.5.5.9 | to 1.5 GHz [Dk/Df measurements] |
| IPC-TM-650- | Pressure vessel method for glass epoxy laminate |
| 2.6.16 | integrity [high pressure cooker test (HPCT)] |
| | Note: Laminates coupons were conditioned in the |
| | pressure vessel in a moisture-saturated atmosphere at |
| | 121° C. for 2 h |

Cure schedule for film curing on heating plate: 10 minutes @170° C. followed by 90 minutes @190° C.

### EXAMPLES

### General Procedures

Epoxy resin varnish formulations were prepared by dissolving the individual resin, curing agent, and accelerator catalyst components in suitable solvents at room temperature and mixing the solutions. Prepregs were prepared by coating the epoxy resin varnish on style 7628 glass cloth (Porcher 731 finish) and drying in a horizontal laboratory treater oven at 173° C. for 2-5 minutes to evaporate the solvents and advance the reacting epoxy/curing agent mixture to a non-tacky B-stage. Laminates were prepared using 1-8 prepreg plies sandwiched between sheets of copper foil (Circuit Foil TW 35 μm) and pressing at 190° C. for 90 minutes. Pressure was adjusted to control a laminate resin content equal to about 43-45 percent.

Several different resin and curing agent systems were tested to verify the performance increase provided by the present invention presented here and these systems are summarized by the following Examples.

### Example 1

| | Example 1 A | | |
|---|---|---|---|
| Varnish Composition Raw | Comparative | | |
| Materials | Example | Example 1 B | Example 1 C |
| Epoxy Resin Solution A | 27.50 g | 27.50 g | 27.50 g |
| Epoxy Resin Solution I | 17.5 g | 17.59 g | 17.59 g |
| TPP [10 percent solids in | 0 g | 0.59 g | 1.19 g |
| DOWANOL PM] | | | |
| 2-PhI [10 percent solids in | 0.74 g | 0.74 g | 0.15 g |
| DOWANOL PM] | | | |
| Acetone | 1.96 g | 1.96 g | 1.96 g |

Films were prepared from the varnish compositions above and tested. The results of testing the films were as follows:

| | Example 1 A | | |
|---|---|---|---|
| | Comparative | | |
| Test Results | Example | Example 1 B | Example 1 C |
| Varnish gel time (s) | 225 | 202 | 227 |
| Film Tg (° C.) | 177 | 179 | 173 |
| Film Td @10 percent wt loss | 349 | 359 | 375 |
| (° C.) | | | |

The films presented in Examples 1B and 1C showed improved thermal stability when compared to the film prepared from the varnish composition of Comparative Example 1A, while maintaining similar Tg. Higher concentration of TPP led to higher Td.

### Example 2

| Varnish Composition Raw materials | Example 2 A | Example 2 B |
|---|---|---|
| Epoxy Resin Solution A | 26.58 g | 26.58 g |
| Hardener Resin Solution I | 9.56 g | 9.56 g |
| TPE [50 percent solids in DOWANOL | 9.56 g | 9.56 g |
| PMA] | | |
| TPP [10 percent solids in DOWANOL | 0.59 g | 1.19 g |
| PM] | | |
| 2-PhI [10 percent solids in DOWANOL | 0.89 g | 0.30 g |
| PM] | | |
| Acetone | 1.20 g | 1.20 g |

Films were prepared from the varnish compositions above and tested. The results of testing the films were as follows:

| Test Results | Example 2 A | Example 2 B |
|---|---|---|
| Varnish gel time (s) | 316 | 344 |
| Film Tg (° C.) | 160 | 163 |
| Film Td @10 percent wt loss (° C.) | 351 | 365 |

The films presented in Examples 2A and 2B showed excellent thermal properties. Higher concentration of TPP led to higher Td.

### Example 3

| | Example 3 A | |
|---|---|---|
| | Comparative | |
| Varnish Composition Raw materials | Example | Example 3 B |
| Epoxy Resin Solution B | 29.58 g | 29.58 g |
| Hardener Resin Solution I | 15.18 g | 15.18 g |
| TPP [10 percent solids in DOWANOL | 0 g | 0.59 g |
| PM] | | |
| 2-MI [20 percent solids in DOWANOL | 0.52 g | 0.30 g |
| PM] | | |
| MEK | 2.34 g | 1.99 g |

Films were prepared from the varnish compositions above and tested. The results of testing the films were as follows:

| | Example 3 A | |
|---|---|---|
| | Comparative | |
| Test Results | Example | Example 3 B |
| Varnish gel time (s) | 224 | 265 |
| Film Tg (° C.) | 179 | 181 |
| Film Td @10 percent wt loss (° C.) | 328 | 334 |

The film prepared from the varnish composition of Example 3B showed improved thermal stability when compared to the film prepared from the varnish composition of Comparative Example 3A, while maintaining similar Tg.

### Example 4

| Varnish Composition Raw materials | Example 4 A | Example 4 B |
|---|---|---|
| Epoxy Resin Solution K | 24.46 g | 0 g |
| Epoxy Resin Solution L | 0 g | 28.81 g |
| Hardener Resin Solution I | 13.56 g | 12.19 g |
| TBBA [60 percent solids in MEK] | 7.04 g | 0 g |
| BPA [60 percent solids in MEK] | 0 g | 3.75 g |
| Boric acid [20 percent solids in | 1.69 g | 1.69 g |
| methanol] | | |
| TPP [10 percent solids in | 0.56 g | 0.56 g |
| DOWANOL PM] | | |
| 2-PhI [10 percent solids in | 0.42 g | 1.12 g |
| DOWANOL PM] | | |

Films were prepared from the varnish compositions above and tested. The results of testing the films were as follows:

| Test Results | Example 4 A | Example 4 B |
|---|---|---|
| Varnish gel time (s) | 248 | 267 |
| Film Tg (° C.) | 181 | 173 |
| Film Td @10 percent wt loss (° C.) | 357 | 342 |

The films presented in Examples 4A and 4B showed excellent thermal properties.

### Example 5

| | Example 5 A | |
|---|---|---|
| | Comparative | |
| Varnish Composition Raw materials | Example | Example 5 B |
| Epoxy Resin Solution M | 25.05 g | 25.05 g |
| Hardener Resin Solution I | 10.73 g | 10.73 g |
| Hardener Resin Solution J | 10.73 g | 10.73 g |
| Boric acid [20 percent solids in | 0.75 g | 0.75 g |
| methanol] | | |
| TPP [10 percent solids in DOWANOL | 0 g | 0.30 g |
| PM] | | |
| 2-PhI [20 percent solids in | 0.14 g | 0.12 g |
| DOWANOL PM] | | |

Films were prepared from the varnish compositions above and tested. The results of testing the films were as follows:

| | Example 5 A | |
|---|---|---|
| | Comparative | |
| Test Results | Example | Example 5 B |
| Varnish gel time (s) | 245 | 208 |
| Film Tg (° C.) | 183 | 173 |
| Film Td @10 percent wt loss (° C.) | 347 | 366 |

The film presented in Example 5B showed improved thermal stability when compared to the film presented in Comparative Example 5A, while showing a minimal decrease of Tg.

### Example 6

| | Example 6 A | | |
|---|---|---|---|
| Varnish Composition Raw | Comparative | | |
| materials | Example | Example 6 B | Example 6 C |
| Epoxy Resin Solution C | 29.1 g | 29.1 g | 1111.5 g |
| Hardener Resin Solution I | 15.6 g | 15.6 g | 594.9 g |
| TPP [10 percent solids in | 0 g | 0.6 g | 45.4 g |
| DOWANOL PM] | | | |
| 2-MI [20 percent solids in | 0.45 g | 0.30 g | 7.4 g |
| DOWANOL PM] | | | |
| DOWANOL PM | 1.1 g | 0.7 g | 10.1 g |

Films were prepared from the varnish compositions above and tested. The results of testing the films were as follows:

| | Example 6 A | | |
|---|---|---|---|
| | Comparative | | |
| Test Results | Example | Example 6 B | Example 6 C |
| Varnish gel time (s) | 248 | 289 | 274 |
| Film Tg (° C.) | 184 | 179 | 172 |
| Film Td @10 percent wt | 327 | 333 | 339 |
| loss (° C.) | | | |

The films presented in Examples 6B and 6C showed improved thermal stability when compared to the film prepared from the varnish composition of Comparative Example 6A, while showing minimal reduction of Tg. Higher concentration of TPP led to higher Td.

### Example 7

### Production of Prepreg and Laminate

The varnish composition described in Example 6C above was used to impregnate 7628 type glass cloth, which was then partly cured in a lab oven to obtain prepreg sheets. A copper clad laminate was produced by stacking 8 plies of the above prepreg between 2 sheets of standard 35 μm copper foil The construction was pressed at 190° C. for 1 hour and 30 minutes. The laminate resin content was about 43 percent.

| Laminate Properties | Test Results |
|---|---|
| Tg (DSC, mid point, 20° C./min), ° C. | 175 |
| CTE <Tg/>Tg (TMA), ppm/K | 75/264 |
| Average CTE (50-260° C.), percent | 3.5 |
| T260 (TMA), min | >60 |
| T288 (TMA), min | 13 |
| Td (TGA, 5 percent wt loss, 10° C./min), ° C. | 338 |
| Water uptake (High Pressure Cooker, 2 h, 121° C.), | 0.33 percent |
| wt percent | |
| High Pressure Cooker 2 h + 2 min dip @288° C., | 100 percent |
| percent pass visual | pass |
| Dk/Df @1 GHz | 4.36/0.012 |
| UL 94, rating | V-0 |
| Copper Peel Strength, 35 μm standard copper, N/cm² | 18.9 |

The laminate described in Example 7 showed an excellent balance of properties, that is superior thermal stability, Tg, flame retardancy, dielectric constants, low moisture uptake, and good copper peel strength.

### Example 8

| Composition of the Varnish Formulation | PARTS SOLUTION |
|---|---|
| Epoxy Resin Solution D | 1058.1 |
| Phenolic Hardener Solution F | 1043.6 |
| SBM† E-40 [40 percent solids in MEK] | 142.4 |
| Boric acid [20 percent solids in methanol] | 71.2 |
| Triphenyl phosphine [10 percent solids in | 28.5 |
| DOWANOL PM] | |
| 2-PhI [20 percent solids in DOWANOL PM] | 8.5 |

The varnish solid content of Example 8 was adjusted to 62 percent with DOWANOL PM. The varnish gel time @170° C. was 253 seconds.

### Example 9

### Production of Prepreg

The varnish composition described in Example 8 above was used to impregnate 7628 type glass cloth, which was then passed through a lab treater to obtain a prepreg with the following characteristics:

| Prepeg Properties | Test Results |
|---|---|
| Resin content (wt percent) | 43 percent |
| Gel time (s) | 63 |
| Minimum melt viscosity @140° C. (Pa s) | 69 |

### Example 10

### Production of Laminate

A copper clad laminate was produced by stacking 9 plies of the above prepreg of Example 9 between 2 sheets of standard 35 μm copper foil. The construction was pressed at 20 N/cm² at 190° C., for 1 hour and 30 minutes. The laminate resin content was about 43 percent.

| Laminate Properties | Test Results |
|---|---|
| Tg (DSC, mid point, 20° C./min), ° C. | 179 |
| CTE <Tg/>Tg (TMA), ppm/K | 83/229 |
| Average CTE (50-260° C.), percent | 3.1 percent |
| T260 (TMA), min | >120 |
| T288 (TMA), min | 29 |
| T300 (TMA), min | 14 |
| Td (TGA, 5 percent wt loss, 10° C./min), ° C. | 357 |
| Td (TGA, 5 percent wt loss, 5° C./min), ° C. | 342 |
| UL 94, rating | V-0 |
| Water uptake (High Pressure Cooker, 2 h, 121° | 0.39 percent |
| C.), wt percent | |
| High Pressure Cooker 2 h + 2 min dip @288° | 100 percent pass |
| C., percent pass visual | |
| Copper Peel Strength, 35 μm standard copper, | 18.8 |
| N/cm² | |
| Toughness (punching test) | pass^{a} |

^{a}“pass” means no delamination after punching test (impact test)

The laminate described in Example 10 showed an outstanding balance of properties, that is superior thermal stability, Tg, flame retardancy, humidity resistance, adhesion to copper, and toughness. The combination of high Tg, high Td, high copper peel strength, and high toughness is especially noteworthy.

### Example 11

| Composition of the Varnish Formulation | PARTS SOLUTION |
|---|---|
| Epoxy Resin Solution E | 573 |
| Phenolic Hardener Solution G | 422 |
| 2-PhI [20 percent solids in DOWANOL | 4.0 |
| PM] | |

The varnish solid content of Example 11 was adjusted to 65 percent with DOWANOL PM. The varnish gel time @170° C. was 271 seconds.

### Example 12

### Production of Prepeg

The varnish described above in Example 11 was used to impregnate 7628 type glass cloth, which was then passed through a lab treater to obtain prepreg with the following characteristics:

| Prepeg Properties | Test Results |
|---|---|
| Resin content (wt percent) | 45 percent |
| Gel time (s) | 68 |
| Minimum melt viscosity @140° C. (Pa s) | 29 |

### Example 13

### Production of Laminate

A copper clad laminate was produced by stacking 8 plies of the above prepreg of Example 12 between 2 sheets of standard 35 μm copper foil. The constructions were pressed at 20 N/cm² at 190° C., for 1 hour and 30 minutes. The laminate resin content was about 43 percent.

| Laminate Properties | Test Results |
|---|---|
| Tg (DSC, mid point, 20° C./min), ° C. | 176 |
| CTE <Tg/>Tg (TMA), ppm/K | 72/292 |
| Average CTE (50-260° C.), percent | 3.5 percent |
| T260 (TMA), min | >120 |
| T288 (TMA), min | 28 |
| T300 (TMA), min | 13 |
| Td (TGA, 5 percent wt loss, 10° C./min), ° C. | 356 |
| Dk/Df @1 MHz | 4.5/0.013 |
| Dk/Df @1 GHz | 4.2/0.014 |
| UL 94, rating | V-0 |
| Water uptake (High Pressure Cooker, 2 h, 121° C.), | 0.43 percent |
| wt percent | |
| High Pressure Cooker 2 h + 2 min dip @288° C., | 100 percent |
| percent pass visual | pass |
| Copper Peel Strength, 35 μm standard copper, N/cm² | 18.0 |
| Toughness (punching test)* | pass |

*“pass” means no delamination after punching test (impact test)

The laminate described in Example 13 showed an outstanding balance of properties, that is superior thermal stability, Tg, flame retardancy, dielectric constants, humidity resistance, adhesion to copper, and toughness. The combination of high Tg, high Td, high copper peel strength, and high toughness is especially noteworthy.

### Example 14

| Composition of the Varnish Formulation | PARTS SOLUTION |
|---|---|
| Epoxy Resin Solution E | 894 |
| Phenolic Hardener Solution G | 623 |
| Talc | 250 |
| BYK‡-W903 | 3 |
| 2-PhI [20 percent solids in DOWANOL PM] | 8 |

The varnish solid content of Example 14 was adjusted to 65 percent with DOWANOL PM. The varnish gel time @170° C. was 288 seconds.

### Example 15

### Production of a Prepeg and Laminate

The varnish described above in Example 14 was used to impregnate 7628 type glass cloth, which was then passed through a lab treater to obtain prepreg. Prepreg gel time @170° C. was 90 seconds. A copper clad laminate was produced by stacking 8 plies of the above prepreg between 2 sheets of standard 35 μm copper foil. The constructions were pressed at 20 N/cm² at 190° C., for 1 hour and 30 minutes. The laminate resin content was about 43 percent.

| Laminate Properties | Test Results |
|---|---|
| Tg (DSC, mid point, 20° C./min), ° C. | 173 |
| CTE <Tg/>Tg (TMA), ppm/K | 40/200 |
| Average CTE (50-260° C.), percent | 2.4 percent |
| T288 (TMA), min | 28 |
| Td (TGA, 5 percent wt loss, 10° C./min), ° C. | 361 |
| Dk/Df @1 MHz | 4.8/0.012 |
| Dk/Df @1 GHz | 4.5/0.012 |
| UL 94, rating | V-0 |
| Copper Peel Strength, 35 μm standard copper, N/cm² | 12.6 |

The laminate described in Example 15 showed an outstanding balance of properties, that is superior thermal stability, Tg, flame retardancy, dielectric constants, and coefficient of thermal expansion in the z direction. The combination of high Tg, high Td, extremely low CTE, and good copper peel strength is especially noteworthy.

### Example 16

| | Example A | | | | Example C | |
|---|---|---|---|---|---|---|
| Varnishes Composition Raw | Comparative | | | | Comparative | |
| materials | Example | | Example B | | Example | |
| EBPAN [75 percent solids in | 71.43 | g | 71.43 | g | 71.43 | g |
| acetone] | | | | | | |
| TBBA [60 percent solids in | 45.43 | g | 45.43 | g | 45.43 | g |
| MEK] | | | | | | |
| BPAN [65 percent solids in | 29.51 | g | 29.51 | g | 29.51 | g |
| acetone] | | | | | | |
| TPP [10 percent solids in | 0 | g | 1.05 | g | 2.10 | g |
| DOWANOL PM] | | | | | | |
| 2E-4MI [20 percent solids in | 0.45 | g | 0.23 | g | 0 | g |
| DOWANOL PM] | | | | | | |
| DOWANOL PMA | 7.45 | g | 7.45 | g | 7.45 | g |

### Example 17

### Production of Prepeg and Laminate

The varnishes described in Example 16 above were used to impregnate 7628 type glass cloth, which was then partly cured in a lab oven to obtain prepreg sheets. A copper clad laminate was produced by stacking 8 plies of the above prepreg between 2 sheets of standard 35 μm copper foil. The construction was pressed at 190° C. for 1 hour and 30 minutes. The laminates resin content was about 43 percent.

| | Example 17 A | | Example 17 C |
|---|---|---|---|
| | Comparative | | Comparative |
| Test Results | Example | Example 17 B | Example |
| Varnish gel time (s) | 175 | 212 | 215 |
| Laminate Tg (° C.) | 190 | 185 | 168 |
| Laminate T288 (min) | 50 | 86 | 137 |

The laminate prepared from Example 17B showed the best balance of properties, that is high Tg and high thermal resistance. On the contrary, the laminate prepared from Comparative Example 17A showed high Tg but lower thermal resistance. The laminate prepared from Comparative Example C showed high thermal resistance but lower Tg.

### Example 18

| Varnish Composition Raw Materials | Example 18 A | Example 18 B |
|---|---|---|
| Epoxy Resin Solution E | 26.74 g | 26.72 g |
| Phenolic Hardener Solution H | 20.94 g | 20.94 g |
| Ethyl triphenyl phosphonium acetate | 0.085 g | 0.149 g |
| [70 percent solids in methanol] | | |
| 2-PhI [20 percent solids in | 0.209 g | 0.060 g |
| DOWANOL PM] | | |

| Test Results | Example 18 A | Example 18 B |
|---|---|---|
| Varnish gel time (s) | 255 | 265 |
| Film Tg (° C.) | 168 | 164 |
| Film Td @10 percent wt loss (° C.) | 354 | 360 |

The films presented in Example 18A and 18B showed excellent thermal properties. Higher concentration of ethyl triphenyl phosphonium acetate led to higher Td.

### Example 19

| | Example 19 A | | |
|---|---|---|---|
| Varnish Composition Raw | Comparative | | |
| Materials | Example | Example 19 B | Example 19 C |
| EBPAN [75 percent solids | 133.3 g | 133.3 g | 133.3 g |
| in acetone] | | | |
| TBBA [60 percent solids | 68.5 g | 68.5 g | 68.5 g |
| in MEK] | | | |
| BPAN [65 percent solids | 68.4 g | 68.4 g | 68.4 g |
| in acetone] | | | |
| TPP [10 percent solids | 0 g | 0.98 g | 0 g |
| in DOWANOL PM] | | | |
| Ethyl triphenyl | 0 g | 0 g | 0.14 g |
| phosphonium acetate | | | |
| [70 percent solids | | | |
| in methanol] | | | |
| 2E-4MI [20 percent | 0.40 g | 0.21 g | 0.20 g |
| solids in DOWANOL PM] | | | |
| DOWANOL PMA | 15.1 g | 15.1 g | 15.1 g |

The gel time was about 240 seconds for all the varnishes in Example 19.

### Example 20

### Production of Prepreg and Laminate

The varnishes described in Example 19 above were used to impregnate 7628 type glass cloth, which were then partly cured in a lab oven to obtain prepreg sheets. A copper clad laminate was produced by stacking 8 plies of the above prepreg between 2 sheets of standard 35 μm copper foil. The construction was pressed at 190° C. for 1 hour and 30 minutes. The laminates resin content was about 43 percent.

| | Example 20 A | Example | Example |
|---|---|---|---|
| Test Results | Comparative Example | 20 B | 20 C |
| Laminate Tg (° C.) | 186 | 184 | 186 |
| Laminate Td (° C.) | 361 | 366 | 364 |
| Laminate T288 (minutes) | 57 | 71 | 66 |
| Copper Peel Strength, | 12.2 | 13.3 | 14.3 |
| 35 μm standard copper | | | |
| (N/cm²) | | | |

The laminates obtained from Example 20B and Example 20C showed improved thermal stability and copper peel strength when compared to the film prepared from Comparative Example 20A, while maintaining high Tg.

While the present invention has been described and illustrated by reference to particular embodiments, those of ordinary skill in the art will appreciate that the present invention lends itself to variations not necessarily illustrated herein. For this reason, then, reference should be made solely to the appended claims for purposes of determining the true scope of the present invention.

What is claimed is:

1. A curable halogen-containing epoxy resin composition comprising:
(a) at least one epoxy resin;
(b) at least one hardener; wherein the hardener is a compound containing a phenolic hydroxyl functionality or a compound capable of generating a phenolic hydroxyl functionality upon heating; and
(c) a catalytic amount of a catalyst system comprising a combination of:
i. at least a first catalyst compound comprising at least one nitrogen-containing catalyst compound; and
ii. at least a second catalyst compound comprising at least one phosphorus-containing catalyst compound;
wherein at least one or more of the above components (a)-(c) is halogenated or contains halogen; or if none of the above components are halogenated wherein the resin composition includes (d) a halogenated or halogen-containing flame retardant compound that does not contain a nitrogen atom; characterized in that the stroke cure gel time of the resin composition is maintained from 90 seconds to 600 seconds when measured at 170° C.; and such that a resultant cured product formed by curing the curable epoxy resin composition contains the following well-balanced properties:
(1) a Tg of greater than 130° C.;
(2) a Td of greater than 320° C.;
(3) a T288 of greater than 1 min;
(4) an adhesion to copper of greater than 10 N/cm; and
(5) a UL94 flame retardancy ranking at least V-1.

2. The epoxy resin composition of claim 1 wherein the epoxy resin is a halogen-containing epoxy resin.

3. The epoxy resin composition of claim 2 wherein the halogen-containing epoxy resin is a brominated epoxy resin.

4. The epoxy resin composition of claim 2 wherein the halogen-containing epoxy resin is diglycidyl ether of tetrabromobisphenol A or derivatives.

5. The epoxy resin composition of claim 1 wherein the epoxy resin is an oxazolidone-modified epoxy resin.

6. The epoxy resin composition of claim 1 wherein the first nitrogen-containing catalyst compound of the catalyst system is an imidazole compound or a derivative thereof.

7. The epoxy resin composition of claim 1 wherein the second phosphorus-containing catalyst compound of the catalyst system does not contain nitrogen and is a phosphine compound, a phosphonium compound, or a mixture thereof.

8. The epoxy resin composition of claim 1 wherein the second phosphorus-containing catalyst compound of the catalyst system is triphenylphosphine.

9. The epoxy resin composition of claim 1 wherein the hardener is a halogen-containing hardener.

10. The epoxy resin composition of claim 1 wherein the hardener is a compound containing a phenolic hydroxyl functionality.

11. The epoxy resin composition of claim 1 wherein the hardener is a phenol or a phenol type compound, selected from the group consisting of bisphenols, halogenated bisphenols, hydrogenated bisphenols, novolac resins, polyalkylene glycols and combinations thereof.

12. The epoxy resin composition of claim 1 wherein the hardener compound contains a brominated flame retardant.

13. The epoxy resin composition of claim 11 wherein the brominated flame retardant is tetrabromobisphenol A or derivatives.

14. The epoxy resin composition of claim 1 wherein the hardener is a compound capable of generating a hydroxyl functionality upon heating.

15. The epoxy resin composition of claim 14 wherein the hardener is a benzoxazine or a polybenzoxazine.

16. The epoxy resin composition of claim 1 including a toughening agent.

17. The epoxy resin composition of claim 16 where the toughening agent is a block copolymer.

18. The epoxy resin composition of claim 1 including a triblock copolymer of styrene-butadiene-methyl methacrylate (SBM) or a triblock copolymer of methyl methacrylate-butyl acrylate-methyl methacrylate (MAM).

19. The epoxy resin composition of claim 1 including a solvent.

20. The epoxy resin composition of claim 1 including a cure inhibitor.

21. The epoxy resin composition of claim 19 wherein the cure inhibitor is boric acid.

22. The epoxy resin composition of claim 1 wherein the amount of hardener present in the composition is such that the epoxy resin to hardener molar ratio is between 2:1 and 1:2.

23. A fiber reinforced composite article comprising a matrix including an epoxy resin composition according to claim 1.

24. The fiber reinforced composite article of claim 23, which is a laminate or a prepreg for an electric circuit.

25. An electric circuit component having an insulating coating of the epoxy resin composition according to claim 1.

26. A process of producing a coated article, comprising coating an article with an epoxy resin composition according to claim 1, and heating the coated article to cure the epoxy resin.

27. A prepreg comprising:
(a) a woven fabric, and
(b) an epoxy resin composition according to claim 1.

28. A laminate comprising:
(a) a substrate including an epoxy resin composition according to claim 1; and
(b) a layer of metal disposed on at least one surface of said substrate.

29. The laminate of claim 28 wherein the substrate further comprises a reinforcement of a woven glass fabric, wherein the epoxy resin and the hardener are impregnated on the woven glass fabric.

30. A printed circuit board (PCB) made of the laminate of claim 28.

31. A process for preparing a resin coated article, the process comprising contacting a substrate with an epoxy resin composition of claim 1.

32. The process of claim 31 wherein the substrate is a metal foil.

33. The process of claim 32 wherein the metal foil is copper.

34. The process of claim 31 wherein the epoxy resin composition further comprises one or more solvent(s).

35. The process of claim 31 wherein the epoxy resin composition is in powder, hot melt, solution or dispersion form.

36. The process of claim 31 wherein the contacting method is selected from the group consisting of powder coating, spray coating, die coating, roll coating, resin infusion and contacting the substrate with a bath comprising the epoxy resin composition.

37. The process of claim 31 wherein the substrate comprises a material selected from the group consisting of glass, fiberglass, quartz, paper, thermoplastic resin, an unwoven aramid reinforcement, carbon, graphite, ceramic, metal and combinations thereof.

38. The process of claim 31 wherein the article is a prepreg, wherein the substrate comprises a material selected from the group consisting of glass, fiberglass, quartz, paper, thermoplastic resin, an unwoven aramid reinforcement, carbon, graphite and combinations thereof; and wherein the contacting occurs in a bath comprising the epoxy resin composition and optionally one or more solvent(s).

39. The process of claim 38 wherein the substrate is glass or fiberglass in the form of a woven cloth or a mat.

40. The process of claim 31 wherein the catalyst is an imidazole or a mixture of imidazoles.

41. The process of claim 31 wherein the catalyst adjuvant is a carboxylic acid; a carboxylic anhydride, or a mixture thereof.

42. The process of claim 31 wherein the catalyst adjuvant is trimellitic anhydride, a derivative of trimellitic anhydride or mixtures thereof.

43. The process of claim 31 wherein the catalyst adjuvant is utilized in an amount of 0.1 percent to 10 percent by weight on total solids.

44. The process of claim 31 wherein the catalyst adjuvant is a liquid at 180° C. with a viscosity of less than 10 Pa·s.

45. The process of claim 31 wherein the catalyst adjuvant is a liquid at 180° C. with an evaporation rate of less than 5 wt percent/min.

46. The process of claim 31 wherein the first nitrogen-containing catalyst compound of the catalyst system is an imidazole compound or a derivative thereof.

47. The process of claim 31 wherein the second phosphorus-containing catalyst compound of the catalyst system does not contain nitrogen and is a phosphine compound, a phosphonium compound, or a mixture thereof.

48. The process of claim 31 wherein the second phosphorus-containing catalyst compound of the catalyst system is triphenylphosphine.

49. The process of claim 31 wherein the epoxy resin is brominated epoxy resin.

50. The process of claim 31 wherein the epoxy resin is an oxazolidone-modified epoxy resin.

51. The process of claim 31 wherein the hardener is a phenol or a phenol type compound selected from the group consisting of bisphenols, halogenated bisphenols, hydrogenated bisphenols, novolac resins, polyalkylene glycols and combinations thereof.

52. The process of claim 31 wherein the hardener compound contains a brominated flame retardant.

53. The process of claim 31 wherein the brominated flame retardant is tetrabromobisphenol A or derivatives.

54. A resin coated article prepared by the process of claim 31.

55. A prepreg prepared by the process of claim 31.
